(19) United States
(12) Patent Application Publication
(10) Pub. No.: US 2015/0008924 A1
(43) Pub. Date: Jan. 8, 2015

(54) NANOPARTICLE RF SHIELD FOR USE IN AN MRI DEVICE

(71) Applicant: KONINKLIJKE PHILIPS N.V., EINDHOVEN (NL)

(72) Inventor: Marinus Johannes Adrianus Maria Van Helvoort, Leende (NL)

(73) Assignee: KONINKLIKE PHILIPS N.V., EINDHOVEN (NL)

(21) Appl. No.: 14/374,943

(22) PCT Filed: Jan. 29, 2013
(86) PCT No.: PCT/IB2013/050738

§ 371 Date: Jul. 28, 2014

Related U.S. Application Data
(60) Provisional application No. 61/593,392, filed on Feb. 1, 2012.

(51) Int. Cl. G01R 33/421

(52) U.S. Cl. CPC G01R 33/4215
USPC 324/318

(57) ABSTRACT

A radio frequency (RF) shield for use in a magnetic resonance imaging (MRI) scanner, the RF shield comprising a carrier (22) and a plurality of nanoparticles (24) which—are immovably connected to the carrier (22),—are aligned along a direction (26) in space, and—have an anisotropic electrical conductivity in the direction (26) in space.

### FIELD OF THE INVENTION

The invention pertains to a nanoparticle radio frequency (RF) shield for use in an operative MR (Magnetic Resonance) scanner.

### BACKGROUND OF THE INVENTION

In magnetic resonance (MR) imaging scanners, a static magnetic field (B₀) is used to align protons in a human body. A gradient magnetic field created by gradient coils may be superimposed to the static magnetic field, so that an obtained signal can be related to an exact location. The gradient magnetic field may be applied by using a pulse technique corresponding to frequencies f_{grad} of up to a few kHz. A so-called radio frequency (RF) coil is operated at radio wave frequencies f_{RF} typically between 10 MHz and 100 MHz, depending on the B₀ magnetic field strength, and a magnetic field strength B₁ to excite the protons or other nuclei of atoms in the human body that subsequently emit RF magnetic resonance signals. RF body coils are commonly used to combine RF transmission and magnetic resonance signal receiving in one device. For at least the reason of a prevention of signal noise in the RF body coil, a decoupling of the gradient coils and the RF body coil by an RF shield at radio frequencies between 10 MHz and 100 MHz is most desirable. Further, a sensitivity of the RF body coil with respect to its position relative to the gradient coils shall be maintained. As an object, the RF shield ideally should attenuate the radio frequency, but should be transparent to frequencies of the pulses of the gradient magnetic field.

In common solutions, electrically conductive plates, made for instance from copper-clad laminate, are furnished with slits such that eddy currents can be induced in the copper shield. These slits are bridged by capacitors, impedances of which are high at low frequencies and low at high frequencies, so that eddy currents cannot be induced for the low frequencies of the gradient coil, but for the high frequencies of the RF body coil.

In conventional RF shielding, illustrated in FIG. 1, an electrically conductive layer of some thickness is provided, in which the RF field generates the eddy currents by induction, which results in a magnetic field that is directed opposite to its cause, thus attenuating the RF field inside the conductive layer. For frequencies below a frequency f₁ that is determined by the electrical conductivity of the layer material, no shielding of the magnetic field occurs (region A of FIG. 1).

Even when the penetration depth is smaller than the layer thickness longitudinal onset of eddy currents cause damping which is proportional to the logarithm of a ratio of the attenuated and the unattenuated RF power, is proportional to the frequency, up to a frequency f₂. At frequency f₂, the penetration depth becomes smaller than the thickness resulting in an exponentially increasing damping (on a logarithmic scale).

For achieving the object described above, it is required that at frequencies of the gradient magnetic field, the shielding should be within region A of the damping curve of FIG. 1, and for RF frequencies, the shielding should be within region C.

In other words: f_{grad}≦f₁ and f_{RF}≧f₂. Unfortunately, f₁ and f₂ are correlated in isotropic conducting materials, like metals, according to:

f₁=(μ₀·σ·d·w)⁻¹

and

f₂=(μ₀·μᵣ·σ·d²)⁻¹=(f₁·w)/(μᵣ·d)

where d denotes a thickness of the electrically conductive material, w a largest dimension of an RF shield, σ the electrical conductivity of the isotropic material, μ₀ the magnetic permeability of the vacuum and μᵣ the relative magnetic permeability of the isotropic material. In MR imaging scanner applications, it is required that μᵣ=1 to prevent distortion of the static magnetic field B₀, thus

f₂/f₁=w/d. (I)

Since the ratio f₂/f₁ is predetermined by the MR scanner imaging application requirements as mentioned above, the ratio of dimensions w, which is given by the object to be shielded, and thickness d of the electrically conductive material, is fixed.

### SUMMARY OF THE INVENTION

It is therefore an object of the invention to provide an RF shield that attenuates radio frequency waves that are used to excite protons or nuclei of atoms in a human body during an operation of an MR imaging scanner, and that at the same time, is transparent to a gradient magnetic field pulse. The phrase “transparent”, as used in this application, shall be understood particularly such that an electromagnetic field is attenuated by the RF shield by less than 6 dB, preferably less than 3 dB in terms of power.

In one aspect of the present invention, the object is achieved by a radio frequency (RF) shield for use in a magnetic resonance (MR) imaging scanner, comprising a carrier and a plurality of nanoparticles, wherein, in a state of operation, the plurality of nanoparticles is immovably connected to the carrier and is aligned along a direction in space, and wherein the plurality of nanoparticles has an anisotropic electrical conductivity in the direction in space.

By making use of a plurality of nanoparticles having an anisotropic electrical conductivity in at least one direction, more design freedom is given for a lay-out of the RF shield, because via

f₁=(μ₀·σ_{w}·d·w)⁻¹ (II)

wherein σ_{w} denotes an electrical conductivity in the direction of a largest dimension of an RF shield which may coincide with the direction of electrical anisotropic conductivity, and f₂=(μ₀·μᵣ·σ_{d}·d²)⁻¹, wherein σ_{d} denotes an electrical conductivity in the direction of a thickness of the RF shield, and with μᵣ=1 (see above), it follows that

f₂=f₁·(w/d)·(σ_{w}/σ_{d}). (III)

The ratio σ_{w}/σ_{d} may represent a degree of the anisotropy of the electrical conductivity in the two directions. The higher the ratio σ_{w}/σ_{d}, the larger an RF shield can be provided at a given thickness d.

In another aspect of the present invention, the carrier essentially encompasses the plurality of nanoparticles, thus providing a protective environment for the electrically conductive plurality of nanoparticles in a mechanically stable arrangement.

In a further aspect of the invention, the carrier has an electrical conductivity that is substantially lower than the anisotropic electrical conductivity of the plurality of nanoparticles. With the electrical conductivity of the carrier being negligible in comparison to the anisotropic electrical conductivity of the plurality of nanoparticles, design options provided for the RF shield will not be affected.

In a preferred embodiment, the direction in space in at least one contiguous portion is a curved line that essentially completely lies in a plane. An alignment like this may allow for an effective attenuation of an RF field directed in a direction that is perpendicular to the curved line, while the RF shield may be transparent to other RF field directions at the same time. The curved line may represent at least a portion of a circular arc or a complete circle. The curved line may also represent another closed figure in the plane, like an ellipse. The term “curved line” may also include closed polygons with rounded corners.

In another aspect of the invention, the carrier is essentially made from a plastic polymer. Plastic polymer carriers may be of light-weight design and may provide a low-cost solution of the protective environment for the nanoparticles. Preferably, the plastic polymer is one of the group of thermoplastic materials which the one of skills in the art is familiar with. Thereby, a number of well-known production methods applicable to thermoplastics, such like injection or compression molding, may become available for a production of the RF shield.

In a preferred embodiment, the anisotropic electrical conductivity of the plurality of nanoparticles can be represented by a tensor having eigenvalues that differ by a factor of at least 50. Such a degree of anisotropy in electrical conductivity may give rise to a large number of design options for the RF shield.

In yet another aspect of the invention, the nanoparticles are selected from a group of materials consisting of carbon nanotubes, carbon fibers, and graphene. The phrase “graphene”, as used in this application, shall be understood particularly as an allotrope of carbon formed by a one-atom-thick planar sheet of carbon atoms that are arranged in a honeycomb crystal lattice. The carbon nanotubes that are familiar to the one of skills in the art shall be understood to comprise single-walled nanotubes (SWNT) as well as multi-walled nanotubes (MWNT). Nanoparticles selected from this group of materials show an intrinsic anisotropic electrical conductivity and may have the potential to be usable for an RF shield which has an anisotropic electrical conductivity in at least one direction.

In a preferred embodiment, the nanoparticles are furnished with at least one electrical dipole member to create a permanent electrical dipole moment. Nanoparticles with a permanent electrical dipole moment may allow for a creation of an anisotropic electrical conductivity in at least one direction by maintaining an alignment of the nanoparticles during a curing state of production of an RF shield by applying an external electrical field. Preferably, heteroatoms such as nitrogen or boron may be used as electrical dipole members.

In yet another preferred embodiment, the nanoparticles may be furnished with a permanent magnetic dipole member to create a permanent magnetic dipole which may provide advantageous options for an alignment of the nanoparticles by applying an external magnetic field during the production of an RF shield. Preferred permanent magnetic dipole members may be iron oxide FeₓO_{y} or ferrites, such as barium ferrite BaO·6FeₓO_{y}.

### BRIEF DESCRIPTION OF THE DRAWINGS

These and other aspects of the invention will be apparent from and elucidated with reference to the embodiments described hereinafter. Such embodiment does not necessarily represent the full scope of the invention, however, and reference is made therefore to the claims and herein for interpreting the scope of the invention.

In the drawings:

FIG. 1 shows a simplified view of a shield damping curve,

FIG. 2 illustrates an RF shield in accordance with the invention, arranged in a coil arrangement of an MR scanner,

FIG. 3 is a simplified cross-sectional view of the RF shield according to FIG. 2, and

FIG. 4 illustrates another embodiment of an RF shield in accordance with the invention.

### DETAILED DESCRIPTION OF EMBODIMENTS

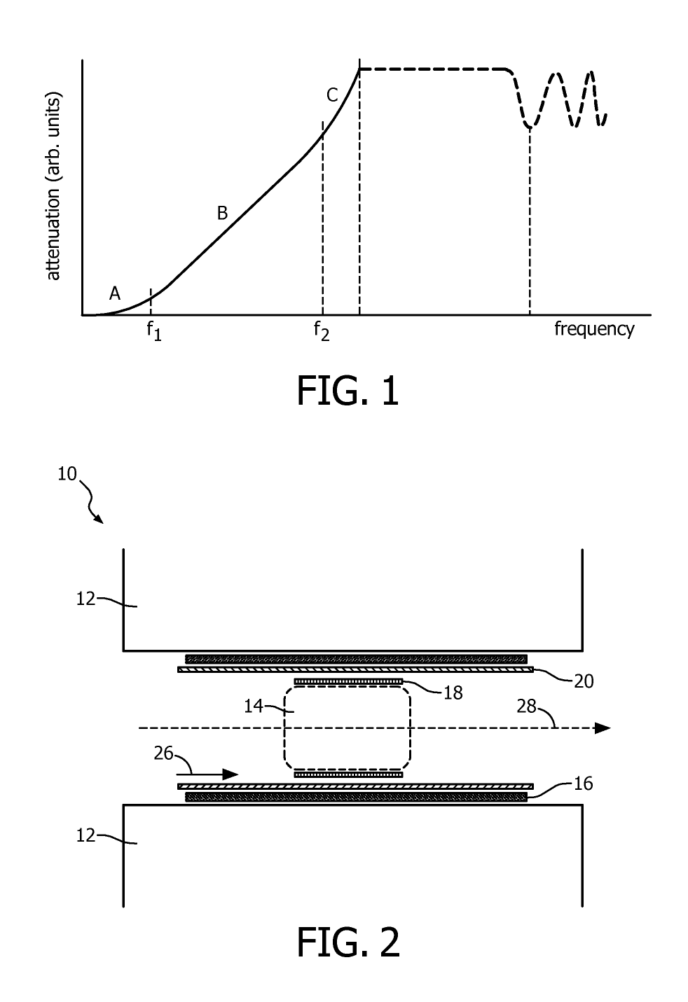

FIG. 1 shows a simplified view of a shield damping curve that has partially been already discussed in the introduction. A typical value for a ratio of cutoff-frequencies f₂ and f₁ of an RF shield to be applied in eq. (III) is f₂/f₁=100 MHz/1 kHz =10⁵. For a material of isotropic electrical conductivity, this would also be the ratio of an RF shield dimension w and a thickness d, according to eq. (I).

For a material with an anisotropic electrical conductivity, however, a constraint for feasible design options is given by the fact that by eq. (III), the ratio of the cutoff-frequencies f₁, f₂ has to equal a product of a ratio of the RF shield dimension w and the thickness d, and a ratio of electrical conductivities σ_{w} and σ_{d} of the RF shield (FIG. 2) in directions that are aligned with the RF shield dimension w and the thickness d, respectively. Although equation (III) seems to imply that only the ratio of the RF shield dimension w and the thickness d is of importance, it should be noted here that a certain absolute thickness d is required to obtain a desired absolute value for f₁ by equation (II), so that the thickness d cannot be made small at discretion to fulfill equation (III).

Thus, when a ratio of the electrical conductivities σ_{w} and σ_{d} of 50 can be achieved, the RF shield dimension w needs to be as large as two thousand times the thickness d. If the required thickness d was 0.5 mm, this results in an RF shield dimension w of 1000 mm.

Illustrated in FIG. 2 is a simplified lateral cross-sectional view of a coil arrangement of a magnetic resonance (MR) scanner 10. The MR scanner 10 comprises a main magnet 12 to create a static magnetic field B₀. The main magnet 12 provides an imaging volume 14 for a patient, in which the static magnetic field B₀ is essentially homogenous and directed along a straight direction which is commonly referred to as the z-axis 28. The MR scanner 10 furthermore comprises gradient coils 16 to generate a gradient magnetic field. The gradient coils 16 are arranged between the main magnet 12 and the imaging volume 14 and are provided to be operated by current pulses having a bandwidth of 3 kHz. Further, an RF body coil 18 is provided to transmit RF waves of RF magnetic field strength B₁, and to subsequently receive RF signals from excited nuclei within the imaging volume 14. The RF body coil 18 is disposed between the gradient coil 16 and the imaging volume 14.

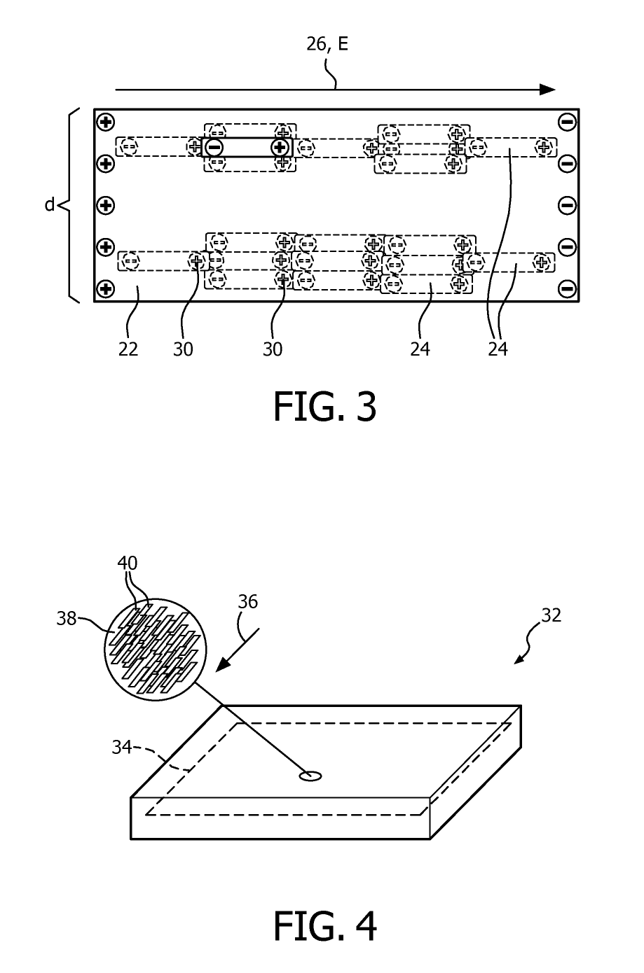

In order to electromagnetically decouple the gradient coils 16 and the RF body coil 18, an RF shield shaped as a hollow cylinder 20 is arranged concentrically to the gradient coils 16 and between the gradient coils 16 and the RF body coil 18. The RF shield comprises a carrier 22 made from thermoplastic polymer polyamide (FIG. 3). In a state of operation inside the MR scanner 10, the hollow cylinder 20 comprises a plurality of nanoparticles 24 that is immovably connected to the carrier 22 such that the carrier 22 completely encompasses each nanotube of the plurality of nanotubes; thus providing mechanical protection and stability.

The plurality of nanoparticles 24 is aligned along a direction 26 in space which is a straight line parallel to the z-axis 28 through a center of the imaging volume 14, wherein the z-axis 28 is arranged parallel to the static magnetic field B₀.

The nanoparticles 24 of the plurality of nanoparticles 24 are formed by (single-walled) carbon nanotubes. These carbon nanotubes have a metal-like electrical conductivity along a direction of extension which coincides with the direction 26 of alignment. In directions perpendicular to the direction of alignment 26, an electrical conductivity of the plurality of carbon nanotubes is lower by a factor of at least 1000. Along the direction of alignment 26, individual nanotubes overlap and may contact adjacent nanotubes which results in a high electrical conductivity in the direction 26 of alignment, so that the plurality of nanoparticles 24 has an anisotropic electrical conductivity in this direction 26.

To obtain a proper alignment of the plurality of nanotubes, each individual carbon nanotube has been furnished with electrical dipole members 30 to create a permanent electrical dipole moment. By applying an external electric field E in a phase during production of the RF shield in which the plastic polymer is in a softened or even liquid state, thus allowing a change of orientation of the electrical dipoles, and by maintaining the external electric field E until the plastic polymer hardens, a uniform alignment may be attained as shown in FIG. 3. The electrical dipole members are formed by boron heteroatoms, each of the nanotubes has been doped with. Due to the lower electronegativity of boron atoms in comparison to carbon atoms, a center of the electric charge of binding electrons is shifted towards the carbon atom, resulting in a permanent electric dipole configuration of the nanotubes.

A mathematical description of the electrical conductivity of the plurality of nanotubes may be provided by a 3×3tensor. In a suitably selected coordinate system, this tensor would be a diagonal matrix, with the diagonal elements being the eigenvalues of the electrical conductivity in the directions of the selected coordinate system. The tensor that represents the anisotropic electrical conductivity of the plurality of carbon nanotubes of the RF shield has eigenvalues that thereby differ by a factor of about 1000.

An electrical conductivity of the carrier is lower than the anisotropic electrical conductivity of the plurality of nanotubes by several orders of magnitude, so that the electrical conductivity of the hollow cylinder 20 is, for practical purposes, completely ruled by that of the aligned nanotubes.

The RF wave that is emitted by the RF body coil 18 has a magnetic field strength B₁ and is essentially directed perpendicular to the static magnetic field B₀ and the gradient field. Thereby, eddy currents are being induced in the RF shield in the direction of alignment 26 of the nanotubes, attenuating the field strength B₁ as their cause of generation. No eddy currents are induced by the magnetic gradient field pulses, as the electrical conductivity of the plurality of nanoparticles 24 in directions perpendicular to the direction of alignment 26 is low.

Another embodiment of an RF shield in accordance with the invention is illustrated in FIG. 4. FIG. 4 shows the RF shield formed as a shielding box 32 for shielding an RF coil electronic unit 34 from the RF transmit field generated by the RF body coil 18 (or local RF transmit coils) of the MR scanner 10, and, vice versa, shielding the RF body coil 18 (and other RF receive coils) from spurious signals generated by the RF coil electronic unit 34. In the state of operation, the RF coil electronic unit 34 is placed inside the shielding box 32. For this application, the shielding effectiveness has to be much higher than for the RF shield of the first embodiment, while for magnetic gradient field frequencies f_{grad} the shielding box 32 still has to be transparent.

The shielding box 32 comprises a carrier 38 made from the injection-moldable thermoplastic acrylonitrile butadiene styrene (ABS), and a plurality of nanoparticles formed by silver-coated carbon nanotubes 40. By the injection molding process, the plurality of nanoparticles is immovably connected to the carrier 38 after the ABS thermoplastic hardens. The silver-coated carbon nanotubes 40 are aligned in parallel to a shorter edge for each of the six faces of the shielding box, respectively. Due to an anisotropic electrical conductivity of the nanoparticles in a direction of alignment 36, eddy currents can be generated in the shielding box 32 to attenuate the RF field, while at the same time, it is transparent to the gradient field frequency f_{grad} in the region of a few kHz.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

REFERENCE SYMBOL LIST:

| | |
|---|---|
| 10 | MR imaging scanner |
| 12 | main magnet |
| 14 | imaging volume |
| 16 | gradient coil |
| 18 | RF body coil |
| 20 | hollow cylinder |
| 22 | carrier |
| 24 | nanoparticle |
| 26 | direction of alignment |
| 28 | z-axis |
| 30 | electrical dipole member |
| 32 | shielding box |
| 34 | electronic unit |
| 36 | direction of alignment |
| 38 | carrier |
| 40 | silver-coated nanotube |
| d | thickness |
| f₁ | cutoff-frequency |
| f₂ | cutoff-frequency |
| f_{grad} | magnetic gradient field frequency |
| f_{RF} | radio wave frequency |
| σ_{d} | electrical conductivity |
| σ_{w} | electrical conductivity |
| w | shield dimension |
| B₀ | static magnetic field |
| B₁ | RF magnetic field |
| E | external electric field |

1. A radio frequency shield for use in a magnetic resonance imaging scanner, comprising:
a carrier,
a plurality of nanoparticles,
wherein, in a state of operation, the plurality of nanoparticles is immovably connected to the carrier and is aligned along a direction of alignment in space, and wherein the plurality of nanoparticles has an anisotropic electrical conductivity in the direction of alignment in space.

2. The radio-frequency shield as claimed in claim 1, wherein the carrier essentially encompasses the plurality of nanoparticles.

3. The radio-frequency shield as claimed in claim 1, wherein the carrier has an electrical conductivity that is substantially lower than the anisotropic electrical conductivity σ_{d}, σ_{w} of the plurality of nanoparticles.

4. The radio-frequency shield as claimed in claim 1, wherein the direction of alignment in space in at least one contiguous portion is a curved line that essentially completely lies in a plane.

5. The radio-frequency shield as claimed in claim 1, wherein the carrier is essentially made from a plastic polymer.

6. The radio-frequency shield as claimed in claim 1, wherein the anisotropic electrical conductivity σ_{d}, σ_{w} can be represented by a tensor having eigenvalues that differ by a factor of at least 50.

7. The radio-frequency shield as claimed in claim 1, wherein the nanoparticles are selected from a group of materials consisting of carbon nanotubes, carbon fibers, and graphene.

8. The radio-frequency shield as claimed in claim 7, wherein the nanoparticles are furnished with at least one electrical dipole member to create a permanent electrical dipole moment.
